(19) United States
(12) Patent Application Publication
(10) Pub. No.: US 2025/0207911 A1
(43) Pub. Date: Jun. 26, 2025

(54) DEPOSITION APPARATUS, MASK FOR DEPOSITION APPARATUS, AND METHOD OF MEASURING GAP BETWEEN MASK FOR DEPOSITION APPARATUS AND SUBSTRATE

(71) Applicant: Samsung Display Co., LTD., Yongin-si (KR)

(72) Inventors: Suk Ha RYU, Yongin-si (KR); Min Goo KANG, Yongin-si (KR); Jun Hyeuk KO, Yongin-si (KR); Seung Chan KIM, Yongin-si (KR); Ya Lim KIM, Yongin-si (KR); Min Chul SONG, Yongin-si (KR)

(21) Appl. No.: 18/774,117

(22) Filed: Jul. 16, 2024

(30) Foreign Application Priority Data
Dec. 21, 2023 (KR) 10-2023-0188444

(51) Int. Cl. G01B 11/14; C23C 14/04; G03F 9/00

(52) U.S. Cl. CPC G01B 11/14; C23C 14/042; G03F 9/703

(57) ABSTRACT

A deposition apparatus includes a substrate, a mask disposed on a first surface of the substrate and including a mask frame supporting an edge area of the substrate, a through-hole formed in the mask frame along the edge area of the substrate, a measurement member disposed between the substrate and the mask frame at a position corresponding to the through-hole and including a measurement hole connected to the through-hole and a measurement camera disposed on a first surface of the mask frame at the position corresponding to the through-hole, wherein the measurement camera measures a first distance to the measurement member exposed through the through-hole and a second distance to the substrate exposed through the measurement hole.

This application claims priority to Korean Patent Application No. 10-2023-0188444, filed on Dec. 21, 2023, and all the benefits accruing therefrom under 35 U.S.C. § 119, the content of which in its entirety is herein incorporated by reference.

### BACKGROUND

### 1. Field

The present invention relates to a deposition apparatus, and more particularly to a deposition apparatus, a mask for a deposition apparatus, and a method of measuring a gap between a mask for a deposition apparatus and a substrate.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions.

Various types of display devices such as liquid crystal displays (LCDs) and organic light emitting displays (OLEDs) have been used. Among the display devices, an organic light emitting display displays an image using organic light emitting elements generating light by recombination of electrons and holes. The organic light emitting display includes a plurality of transistors providing driving currents to the organic light emitting elements.

A thin film transistor (TFT) manufacturing process used with manufacturing the display device may use a sputtering technique and a plasma enhanced chemical vapor deposition (PECVD) technique according to the material to be deposited. The sputtering technique is a technique that deposits atoms that are sputtered from a material that is to be deposited on a glass substrate by hitting the material that is to be deposited with ions while in a vacuum state, and that is mainly used to deposit a metal material. The plasma enhanced chemical vapor deposition technique is a technique that generates a potential difference between electrodes disposed in a chamber by applying high-frequency power thereby decomposing a gas, including a material to be deposited, into a plasma state via the potential difference, and depositing a deposition material onto a substrate. The plasma enhanced chemical vapor deposition technique is used to deposit a semiconductor or an insulating film.

In a deposition apparatus that performs such a deposition process, a deposition shadow defect may occur due to a gap between a substrate, which is a deposition target, and a mask frame disposed on the lower side of the substrate.

The deposition shadow defect refers to a defect in an area where a pattern deposition thickness is smaller than a target thickness which occurs when deposition is performed in a state in which a fine metal mask and the substrate are spaced apart from each other. Here, the closer the gap is to about 0 um, the smaller the shadow size is.

In order to confirm such a gap, flatness of each of a mask support portion and an electrostatic chuck may be adjusted and the gap may then be measured using a gap gauge, for example, when setting up the deposition apparatus.

When the gap gauge measures the gap while being in direct contact with a contact surface between the mask frame and the substrate as described above, damage to the mask frame and the substrate may occur due to the gap gauge. As such, the gap may become different from that in an initial state before being measured due to damage which may be caused by being measured, and, when measuring the gap several times, it may become difficult to accurately measure the gap at the same position when the damage has already occurred.

### SUMMARY

Aspects of the invention provide a deposition apparatus, a mask for a deposition apparatus, and a method of measuring a gap between the mask for a deposition apparatus and a substrate capable of measuring a gap via a measurement member and a measurement camera rather than measuring the gap in a state in which a gap gauge is in direct contact with a contact surface between a mask frame and the substrate.

However, aspects of the invention are not restricted to those set forth herein. The above and other aspects of the invention will become more apparent to one of ordinary skill in the art to which the invention pertains by referencing the detailed description of the present disclosure given below.

According to an aspect of the invention, there is provided a deposition apparatus which includes a substrate, a mask disposed on a first surface of the substrate and including a mask frame supporting an edge area of the substrate, a through-hole formed in the mask frame along the edge area of the substrate, a measurement member disposed between the substrate and the mask frame at a position corresponding to the through-hole and including a measurement hole connected to the through-hole and a measurement camera disposed on a first surface of the mask frame at the position corresponding to the through-hole, wherein the measurement camera measures a first distance to the measurement member exposed through the through-hole and a second distance to the substrate exposed through the measurement hole.

In an embodiment, the measurement member may be positioned on a second surface of the mask frame to be disposed opposite to the first surface of the mask frame.

In an embodiment, the measurement member may further include a cover portion that is an area other than the measurement hole, wherein the measurement hole is positioned at a center of the cover portion and is formed to have a smaller size than the through-hole and penetrate through the cover portion.

In an embodiment, the cover portion may be attached to the second surface of the mask frame to open a portion of the through-hole to the same size as the measurement hole and to cover the remaining area of the through-hole.

In an embodiment, the measurement member may be formed as a thin film.

In an embodiment, a deposition apparatus may further include a controller for storing the first distance and the second distance measured by the measurement camera and calculating a gap between the substrate and the mask by calculating a difference value between the stored first distance and the stored second distance.

In an embodiment, the measurement camera may be coupled to and decoupled from the first surface of the mask frame at the position corresponding to the through-hole.

In an embodiment, the mask frame may include a metal, and the measurement camera includes a magnetic force applying portion coupling the measurement camera to the mask frame by generating a magnetic force and decoupling the measurement camera from the mask frame by blocking the magnetic force.

In an embodiment, the deposition apparatus may further include a connection support portion positioned between the measurement camera and the magnetic force applying portion for connecting the measurement camera to the magnetic force applying portion.

In an embodiment, the mask may further include a mask pattern portion positioned in a central area of the mask frame and disposed on the first surface of the substrate.

In an embodiment, the deposition apparatus may further include a mask support portion positioned on the first surface of the mask frame together with the measurement camera for supporting the mask on the first surface of the mask frame.

In an embodiment, the deposition apparatus may further include an electrostatic chuck (ESC) positioned on a second surface of the substrate disposed opposite to the first surface of the substrate and a magnetic force generator positioned on a first surface of the electrostatic chuck.

According to an aspect of the invention, there is provided a mask for a deposition apparatus including a mask pattern portion, a mask frame positioned at an edge of the mask pattern portion, a through-hole formed in the mask frame and a measurement member positioned on the mask frame at a position corresponding to the through-hole and including a measurement hole connected to the through-hole.

In an embodiment, the measurement member may further include a cover portion that is an area other than the measurement hole, wherein the measurement hole is positioned at a center of the cover portion and is formed to have a smaller size than the through-hole and to penetrate through the cover portion.

In an embodiment, the cover portion may be attached onto the mask frame to open a portion of the through-hole to the same size as the measurement hole and to cover the remaining area of the through hole.

According to an aspect of the invention, there is provided a method of measuring a gap between a mask for a deposition apparatus and a substrate, the method including preparing a mask including a mask pattern portion and a mask frame positioned at an edge of the mask pattern portion and having at least one through-hole, disposing a measurement member on the mask frame, the measurement member having a measurement hole connected to the through-hole, disposing a substrate on an upper side of the mask frame, disposing a measurement camera on a lower side of the mask frame and measuring distances through the measurement camera, wherein the measurement camera measures a first distance to the measurement member exposed through the through-hole and a second distance to the substrate exposed through the measurement hole.

In an embodiment, the disposing of the measurement member on the mask frame may include thermally bonding the measurement member onto the mask frame.

In an embodiment, the measuring of the distances through the measurement camera may include coupling the measurement camera to the lower side of the mask frame so as to correspond to the through-hole and decoupling the measurement camera from the mask frame when the measurement of the distances are completed through the measurement camera, wherein the coupling of the measurement camera and the decoupling of the measurement camera are repeated to correspond to the number of at least one through-hole.

In an embodiment, the measurement camera may include disposing a magnetic force applying portion coupling and decoupling the measurement camera to and from the mask frame by generating and blocking a magnetic force, wherein in the coupling of the measurement camera, the magnetic force applying portion couples the measurement camera to the mask frame by generating the magnetic force, and in the decoupling of the measurement camera, the magnetic force applying portion decouples the measurement camera from the mask frame by blocking the magnetic force.

In an embodiment, the method may further include calculating a difference value between the first distance and the second distance as the gap between the mask for a deposition apparatus and the substrate. According to an embodiment, it is possible to provide a deposition apparatus, a mask for a deposition apparatus, and a method of measuring a gap between a mask for a deposition apparatus and a substrate, wherein the method is capable of measuring a gap through a measurement member and a measurement camera rather than measuring the gap in a state in which a gap gauge is in direct contact with a contact surface between a mask frame and the substrate.

In an embodiment, distances may be measured with the measurement camera through a measurement hole of the measurement member and a through-hole of the mask frame, wherein the gap may be calculated based on the measured distances, and accordingly, it is possible to perform non-destructive measurement without damaging the substrate and the mask frame unlike an existing method of measuring the gap in a state in which the gap gauge is in direct contact with the contact surface.

In an embodiment, depending on a gap measurement position where the measurement member is positioned, it is possible to attach and detach the measurement camera to and from the mask frame, wherein such attachment and detachment of the measurement camera is implemented by a magnetic force, and accordingly, it is possible to measure the gap while simply changing a position of the measurement camera.

Further, in an embodiment, it is possible to accurately measure the gap at the same position even when measuring the gap several times because the gap measurement position is specified by the measurement member.

In an embodiment, by using the measurement camera, errors due to scattering of light may be fewer, and it is possible to confirm and discriminate an actual image for each measurement position.

### BRIEF DESCRIPTION OF THE DRAWINGS

The above and other aspects and features of the invention will become more apparent by describing in detail exemplary embodiments thereof with reference to the attached drawings, in which:

FIG. 1 is a cross-sectional view of a deposition apparatus, according to an embodiment;

FIG. 2 is an enlarged cross-sectional view of the deposition apparatus of FIG. 1, according to an embodiment;

FIG. 3 is an enlarged cross-sectional view of an area of a measurement hole of a measurement member and a through-hole of a mask frame of FIG. 2, according to an embodiment;

FIG. 4 is a top view of the measurement member of FIG. 3 viewed from above, according to an embodiment;

FIG. 5 is a bottom view of the mask frame of FIG. 3 viewed from below, according to an embodiment;

FIG. 6 is a flowchart illustrating a method of measuring a gap between a mask and a substrate, according to an embodiment;

FIG. 7 is a cross-sectional view of the mask and a mask support portion, according to an embodiment;

FIG. 8 is an enlarged view of the through-hole of the mask frame in FIG. 7, according to an embodiment;

FIG. 9 is a cross-sectional view of the measurement member, the mask, and the mask support portion, according to an embodiment;

FIG. 10 is an enlarged view of the measurement member and the through-hole of the mask frame of FIG. 9, according to an embodiment;

FIG. 11 is a view illustrating a state in which the substrate is disposed on the upper surface of the measurement member and the mask so as to be spaced apart from the measurement member and the mask, according to an embodiment;

FIG. 12 is an enlarged view of a partial area of the substrate, the measurement member, and the mask of FIG. 11, according to an embodiment;

FIG. 13 is a view illustrating a state in which the substrate is disposed on the measurement member and the mask, according to an embodiment;

FIG. 14 is an enlarged view of a partial area of the substrate, the measurement member, and the mask of FIG. 13, according to an embodiment;

FIG. 15 is a top view of the substrate, the measurement member, and the mask of FIG. 13 viewed from above, according to an embodiment;

FIG. 16 is a view illustrating a state in which a measurement camera module is disposed on the lower side of the mask frame, according to an embodiment;

FIG. 17 is an enlarged view of an installation area of the measurement camera module of FIG. 16, according to an embodiment;

FIG. 18 is a view illustrating a state in which the measurement camera of FIG. 17 measures a first distance, according to an embodiment;

FIG. 19 is a view illustrating a state in which the measurement camera of FIG. 17 measures a second distance, according to an embodiment;

FIG. 20 is a view illustrating the first and second distances measured by the measurement camera of FIG. 17, according to an embodiment; and

FIG. 21 is a view illustrating a state of a lower surface of the mask frame when the measurement camera of FIG. 17 measures the second distance, according to an embodiment.

### DETAILED DESCRIPTION

The invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. The same reference numbers indicate the same components throughout the specification. In the attached figures, the thickness of layers and regions may be exaggerated for clarity.

It will also be understood that when a layer is referred to as being disposed “on”, “connected to” or “coupled to” another element, layer or substrate, it can be directly on the other element, layer or substrate, or intervening elements, layers or substrates may also be present. Likewise, those referred to as “Below”, “Left”, and “Right” include cases where they are directly adjacent to other elements or cases where another layer or other material is interposed. To this end, the term “connected” may refer to physical, electrical, and/or fluid connection, with or without intervening elements.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

Features of each of various embodiments of the invention may be partially or entirely combined with each other and may technically variously interwork with each other, and respective embodiments may be implemented independently of each other or may be implemented together in association with each other.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, ZZ, or the like. As used herein, the term “and/or” includes any and all combinations of one or more of the associated listed items.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the invention. Further, the blocks, units, parts, and/or modules of some embodiments may be physically combined into more complex blocks, units, parts, and/or modules without departing from the scope of the invention.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the invention will be described with reference to the accompanying drawings.

A deposition apparatus, according to an embodiment, may be a chemical vapor deposition apparatus, a physical vapor deposition apparatus, an atomic layer deposition apparatus, or a sputtering apparatus.

In an embodiment, the deposition apparatus may be used in a thin film transistor manufacturing apparatus or a semiconductor manufacturing process that manufactures substrates for application with integrated circuit (IC) devices, display devices, solar cells, and the like. For example, the deposition apparatus, according to an embodiment, may be used to deposit amorphous silicon (a-Si) or deposit an insulating film and a protective film when manufacturing a thin film transistor (TFT).

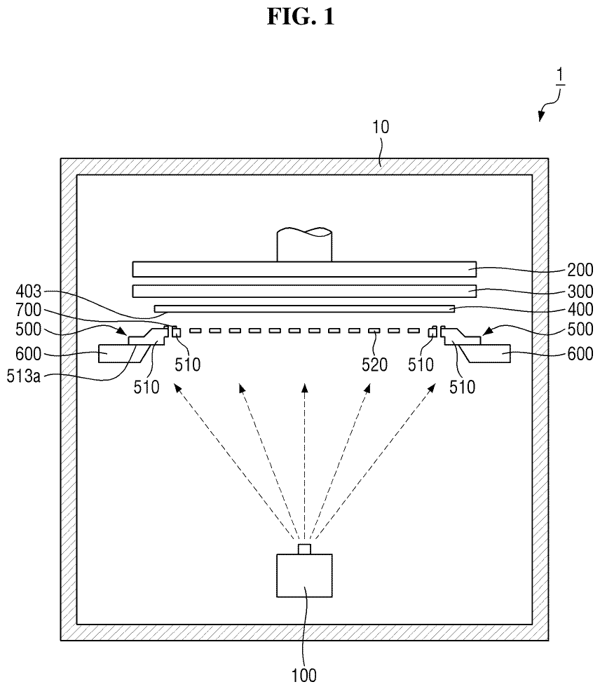

FIG. 1 is a cross-sectional view of a deposition apparatus, according to an embodiment.

In an embodiment and referring to FIG. 1, a deposition apparatus 1 is shown and may include a chamber 10, a deposition source 100, a magnetic force generator 200, an electrostatic chuck 300, a substrate 400, and a mask assembly 500, 600.

In an embodiment, the chamber 10 defines a space where a deposition process is performed, and may be connected to a vacuum pump (not illustrated), such as a turbo molecular pump (MP), so as to maintain the inside of the chamber 10 in a vacuum state during the deposition process. In addition, the chamber 10 may further include an adsorption prevention plate (not illustrated) disposed to surround the inner wall surfaces. Here, the adsorption prevention plate may prevent an organic material that is ejected from the deposition source 100 but is not deposited on the substrate 400 from being adsorbed on the inner wall surfaces of the chamber 10.

In an embodiment and referring to FIG. 1, the chamber 10 may have a hexahedral shape with a rectangular cross-sectional shape, but is not limited thereto, and in other embodiments may have a polyhedral shape such as a heptahedral shape or an octahedral shape, or a cylindrical shape.

In an embodiment, the deposition source 100 is positioned below the mask assembly 500, 600 inside the chamber 10, and supplies an organic material to the substrate 400 through a mask pattern portion 520 of the mask assembly 500, 600, which will be described later. That is, the deposition source 100 serves to supply and eject the organic material in a direction toward a deposition surface of the substrate 400 which is positioned at an upper portion inside the chamber 10.

In an embodiment, the deposition source 100 is in the form of a crucible including the organic material therein, and may deposit the organic material on the substrate 400 by evaporating the organic material with heat. The deposition apparatus 1 may further include a heater (not illustrated) for heating the organic material.

In an embodiment, heaters (not illustrated) may be provided on both sides of the deposition source 100, to heat the deposition source 100 to heat and sublimate the organic material contained within the deposition source 100.

In an embodiment, the magnetic force generator 200 may be disposed inside the chamber 10 on an upper surface of the electrostatic chuck 300, which is a first surface of the electrostatic chuck 300, and may be positioned to face the mask assembly 500, 600 with the substrate 400, which is a deposition target, interposed therebetween.

In an embodiment, the magnetic force generator 200 may be formed of a magnet unit, and a mask pattern portion 520, which will be described later, of the mask assembly 500 600 and which may be in close contact with the substrate 400 through a magnetic force generated by the magnet unit. As an example, in an embodiment, when the magnetic force generator 200 applies the magnetic force to a mask 500, which will be described later, the mask 500 may be configured to move toward the substrate 400, but the invention is not limited thereto. In this case, the mask 500 may be made of a metal.

In an embodiment, the electrostatic chuck 300 may be disposed inside the chamber 10, and may be positioned on an upper surface of the substrate 400, which is a second surface of the substrate 400 and which is disposed opposite to a lower surface 403 of the substrate 400, which is a first surface of the substrate 400.

In an embodiment, the electrostatic chuck 300 is an electrostatic chuck (ESC), and may serve to hold the substrate 400 in place using electrostatic force. That is, the electrostatic chuck 300 may serve to support and fix the substrate 400 inside of the chamber 10.

Here, the electrostatic chuck 300 has been used to fix the substrate 400 in place, but the invention is not limited thereto, and any device or any structure such as a clamp, a pin, or an adhesive chuck that may be installed inside the chamber 10 and that may support the substrate 400 may be used to fix the substrate 400 in place.

In an embodiment, the substrate 400 may be positioned between the electrostatic chuck 300 and the mask assembly 500, 600, and may be disposed at a position corresponding to a mask pattern portion 520.

In an embodiment, the substrate 400 may be made of an insulating material selected from the group consisting of glass, quartz, ceramic, plastic, and the like, or made of a metallic material such as stainless steel, but is not limited thereto.

In an embodiment, the mask assembly 500, 600 may be positioned on the lower surface 403 of the substrate 400, and may include a mask 500 and a mask support portion 600.

In an embodiment, the mask 500 may include a mask frame 510 positioned in an edge area of the mask assembly 500, 600 and a mask pattern portion 520 positioned in a central area of the mask assembly 500, 600.

In an embodiment, the mask frame 510 may serve to support an edge area of the substrate 400 on the lower surface 403 of the substrate 400, and may be made of the same metal material as the mask pattern portion 520 or may be made of a metal having greater rigidity than the mask pattern portion 520.

In an embodiment, the mask frame 510 may be formed in a rectangular frame shape in which a central opening corresponding to the substrate 400, which is the deposition target, is formed so that the deposition process of the substrate 400 may be performed.

In an embodiment, the mask pattern portion 520 may be disposed in a central opening area of the mask frame 510 and may be positioned between the lower surface 403 of the substrate 400 and the deposition source 100.

In an embodiment, both end portions of the mask pattern portion 520 may be fixed and coupled to the mask frame 510. The end portions of the mask pattern portion 520 may be made of any one of stainless steel (SUS), an Invar alloy, nickel, cobalt, a nickel alloy, and a nickel-cobalt alloy.

In an embodiment, the mask pattern portion 520 may be formed in a rectangular plate shape to correspond to the central opening area of the mask frame 510. The mask pattern portion 520 may be fixed to the mask frame 510 or to a plurality of mask pattern portions 520 that are individually formed and that may each be fixed to the mask frame 510.

Here, both end portions of the mask pattern portion 520 may be fixed and coupled to the mask frame 510, and in this case, the mask pattern portion 520 may be fixed onto the mask frame 510 by a welding method, which is a thermal bonding method. Welding may be spot welding, and the spot welding may minimize deformation by setting a plurality of welding points and performing welding at each of the plurality of welding points.

In an embodiment, when the mask frame 510 is made of a metal having a greater rigidity than the mask pattern portion 520, thermal deformation of the mask pattern portion 520 due to the welding when the mask pattern portion 520 is fixed to the mask frame 510 may be suppressed.

In an embodiment, the mask support portion 600 may be disposed to be in contact with a contact lower surface 513a, which is a contact first surface of the mask frame 510, and may serve to support an edge of the mask frame 510. The mask support portion 600 may be disposed outside a movement path of the organic material supplied from the deposition source 100 to the substrate 400.

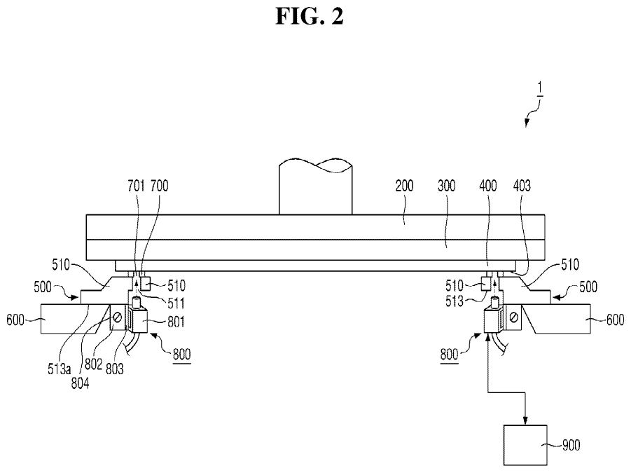

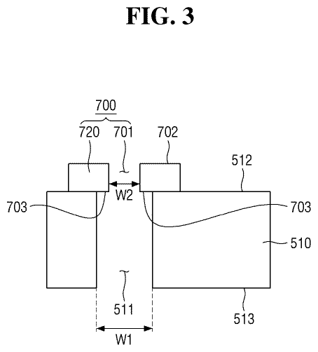

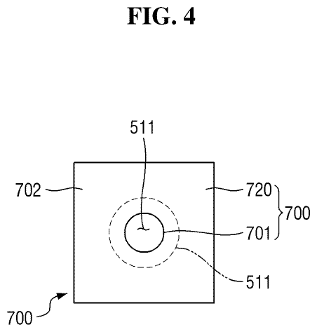

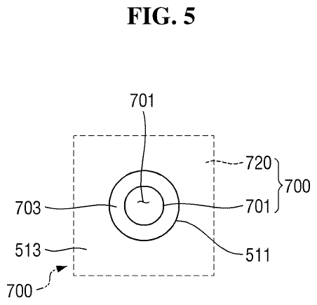

According to embodiments, FIG. 2 is an enlarged cross-sectional view of the deposition apparatus of FIG. 1, FIG. 3 is an enlarged cross-sectional view of an area of a measurement hole of a measurement member and a through-hole of a mask frame of FIG. 2, FIG. 4 is a top view of the measurement member of FIG. 3 viewed from above, and FIG. 5 is a bottom view of the mask frame of FIG. 3 viewed from below. In FIG. 2, the chamber 10 of FIG. 1 has been omitted in order to illustrate components on an enlarged scale.

In an embodiment and referring to FIG. 2, the deposition apparatus 1 may further include a through-hole 511 disposed in the mask frame 510, a measurement member 700 disposed between the lower surface 403 of the substrate 400 and the mask frame 510, a measurement camera module 800 disposed on the contact lower surface 513a of the mask frame 510, and a controller 900.

In an embodiment and referring to FIG. 2, the measurement camera module 800 may include a measurement camera 801, a magnetic force applying portion 802, and a connection support portion 803.

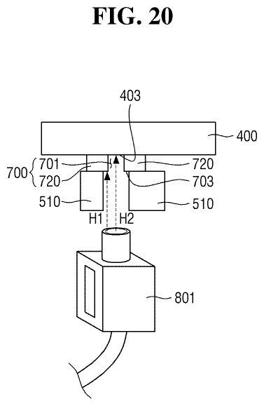

In an embodiment, the measurement camera 801 may measure a first distance H1 from the measurement camera 801 to the measurement member 700 and a second distance H2 from the measurement camera 801 to the substrate 400 through the through-hole 511 (see FIG. 20). Here, since the measurement camera 801 is used to measure a gap, errors due to scattering of light caused by a surface quality of a material may be fewer than those in the case of using a laser displacement sensor, and it may be possible to confirm and discriminate an actual image for each measurement position.

In an embodiment, the measurement camera 801 may be installed on the contact lower surface 513a of the mask frame 510 at a position corresponding to the through-hole 511 such that the measurement camera 801 is aligned with the through-hole 511.

In an embodiment, the measurement camera 801 may be installed to be coupled to and decoupled from the contact lower surface 513a by the connection support portion 803 and the magnetic force applying portion 802. The measurement camera 801 may also be separately embedded in the mask frame 510, and in this case, a battery of the measurement camera 801 may be provided together in the mask frame 510 to enable measurement of the gap even in a vacuum state. In addition, in another embodiment, a laser displacement sensor or a capacitance sensor may be used instead of the measurement camera 801.

In an embodiment, the magnetic force applying portion 802 may serve to fix the measurement camera 801 in place by generating a magnetic force and may decouple the measurement camera 801 by blocking the magnetic force.

In an embodiment, the magnetic force applying portion 802 may include an on-off switch 804, and may couple the measurement camera 801 to the contact lower surface 513a of the mask frame 510 by generating the magnetic force in an on-state and may decouple the measurement camera 801 from the contact lower surface 513a of the mask frame 510 by blocking the magnetic force in an off-state. In this case, the mask frame 510 may be made of a metal.

In an embodiment, the connection support portion 803 may be made of a magnetic material having magnetism when the magnetic force applying portion 802 generates the magnetic force. According to the generation of the magnetic force by the magnetic force applying portion 802, the measurement camera 801 may be coupled to and decoupled from the contact lower surface 513a of the mask frame 510 by turning the magnetic force applying portion 802 on and off, respectively.

In an embodiment, the connection support portion 803 may be positioned between the measurement camera 801 and the magnetic force applying part 802, and may have one surface coupled integrally with the measurement camera 801, another surface coupled integrally with the magnetic force applying portion 802, and an upper surface in direct contact with the contact lower surface 513a of the mask frame 510.

In an embodiment, when the magnetic force applying portion 802 generates the magnetic force, the connection support portion 803 becomes magnetized, and accordingly, the upper surface of the connection support portion 803 may be attached and fixed to the contact lower surface 513a of the mask frame 510 which is made of the metal, such that the measurement camera 801 is coupled integrally with the connection support and may be disposed at the position corresponding to the through-hole 511.

In an embodiment, the controller 900 may be electrically connected to the measurement camera module 800, and may store the first distance Hl and the second distance H2 that were measured by the measurement camera 801 and calculate a gap between the substrate 400 and the mask 500 which is a difference value between the first distance H1 and second distance H2.

In an embodiment, the controller 900 may calculate a focusing height at which the measurement camera 801 focuses on the measurement member 700, calculate a focusing height at which the measurement camera 801 focuses on the substrate 400, and calculate a difference gap which is the difference between the focusing heights. That is, the controller 900 may calculate data measured by the measurement camera 801 by receiving distance values, and calculating the data as the gap.

In an embodiment and referring to FIG. 3, the through-hole 511 may be formed in the mask frame 510 to penetrate through a lower surface 513, which is a first surface of the mask frame 510, and an upper surface 512, which is a second surface of the mask frame 510. Here, at least one through-hole 511 may be formed along the edge area of the substrate 400.

In an embodiment, the measurement member 700 may be disposed on the upper surface 512 of the mask frame 510 at the position corresponding to the through hole 511.

In an embodiment, the measurement member 700 may be formed to have a very small thickness as an ultra-thin film, and accordingly, the edge area of the substrate 400 is seated on and supported by the mask frame 510. That is, the edge area of the substrate 400 and the mask frame 510 appear to be almost attached to each other with the naked eye, and a thickness of the measurement member 700 and a gap between the edge area of the substrate 400 and the mask frame 510, as illustrated in the FIGS. 2 and 3, are a thickness and gap that is illustrated for describing components, and are not limited thereto.

In an embodiment, the measurement member 700 may include a measurement hole 701 positioned in a central area of the measurement member 700 and a cover portion 720 that is disposed in an area other than the measurement hole 701.

In an embodiment, the measurement hole 701 may be formed to penetrate a plate surface in the central area of the measurement member 700, and may be disposed to be aligned with the through-hole 511.

In an embodiment, the measurement hole 701 may be positioned at the center of the cover portion 720, and may have a diameter W2 which may be smaller than a diameter W1 of the through-hole 511.

In an embodiment, the cover portion 720 is the remaining area, excluding the measurement hole 701, in an entire area of the measurement member 700, and may be attached to the upper surface 512 of the mask frame 510 to open a portion of the through-hole 511 to the same size as the measurement hole 701 and to cover the remaining area of the through-hole 511.

In an embodiment and referring to FIG. 4, when the measurement member 700 of FIG. 3 is viewed from an upper surface 702 of the cover portion 720, the cover portion 720 covers a portion of the through-hole 511, such that the inside of the through-hole 511 may be viewed through the measurement hole 701 which is smaller than the through-hole 511.

In an embodiment and referring to FIG. 5, when the mask frame 510 of FIG. 3 is viewed from the lower surface 513 of the mask frame 510, the entire measurement member 700 is not viewed, and a portion of the measurement member 700 which is exposed through the lower surface 513 of the mask frame 510 may be viewed through the through-hole 511.

In an embodiment, since the through hole 511 is greater in size than the measurement hole 701, the measurement hole 701 positioned at the center of the measurement member 700 and a portion of a lower surface 703 of the cover portion 720 where the measurement hole 701 is positioned may be viewed through the through-hole 511.

In an embodiment, a portion of the lower surface 703 of the cover portion 720 where the measurement hole 701 is positioned is exposed through the through-hole 511, and accordingly, a portion of the lower surface 703 of the cover portion 720 and the inside of the measurement hole 701 may be viewed through the through-hole 511.

A process of depositing a deposition material on the deposition surface of the substrate 400 in the deposition apparatus 1, according to an embodiment, is described below.

First, the mask 500 is fixed to the mask support portion 600, and the substrate 400 is disposed above the mask 500, according to an embodiment.

Subsequently, in an embodiment, the deposition source 100 positioned at a lower portion in the chamber 10 sprays the organic material toward the mask 500. In detail, when power is applied to the heater (not illustrated) that is connected to the deposition source 100, the deposition source 100 containing the organic material is heated, and accordingly, the organic material contained therein is heated and sublimated to be sprayed toward the mask 500. In this embodiment, the inside of the chamber 10 is maintained at a high vacuum and a high temperature.

In an embodiment, when the organic material is sprayed, the organic material is deposited on the deposition surface of the substrate 400 according to patterns of the mask pattern portion 520. By repeating this process, a multilayer organic thin film may be formed on the substrate 400. The deposition material is not limited to the organic material.

In addition, although not illustrated, the deposition apparatus 1, according to an embodiment, may include a thickness monitoring sensor for measuring a speed of the evaporating organic material, a thickness controller for controlling the deposition source 100 according to a measured thickness, a shutter capable of blocking the evaporated organic material from the deposition source 100, and an aligner for aligning the substrate 400 and the mask 500 with each other. However, the deposition apparatus 1 is not limited thereto.

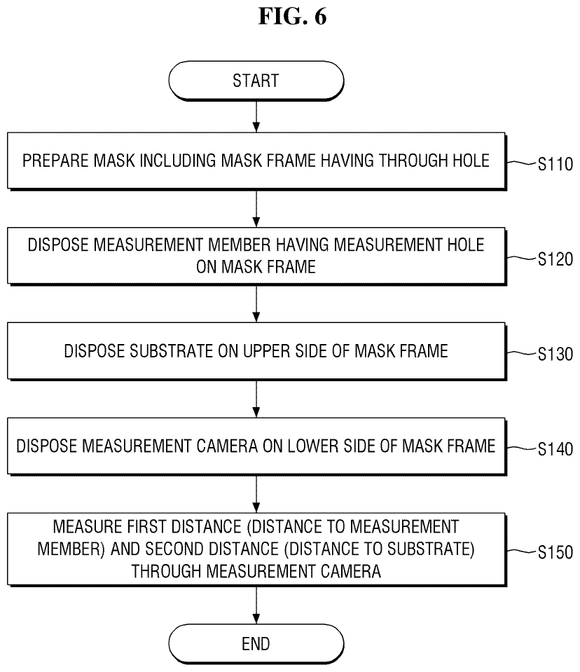

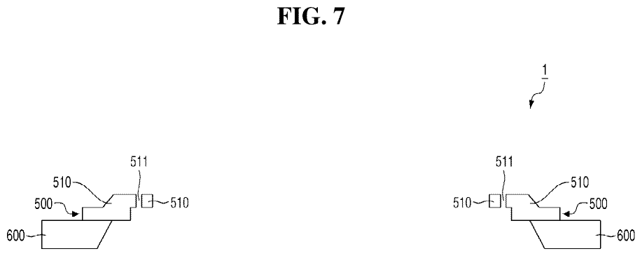

Hereinafter, a method of measuring a gap between the mask 500 and the substrate 400, according to an embodiment, will be described with reference to FIGS. 6 to 21. Here, the mask 500 includes the mask pattern portion 520 as illustrated in FIG. 1, but the mask pattern portion 520 has been omitted in FIGS. 7 to 21 for describing the method of measuring a gap.

In an embodiment and referring to FIG. 6, a flowchart illustrating a method of measuring a gap between a mask and a substrate is shown, and the method of measuring the gap between the mask 500 and the substrate 400 may include the following steps, according to an embodiment.

First, the method of measuring the gap between the mask 500 and the substrate 400 may include preparing the mask 500 (S110 in FIG. 6).

Here, the mask 500 is a mask for use in deposition apparatus 1 and may be prepared as the mask 500 including the mask frame 510 having the through-hole 511.

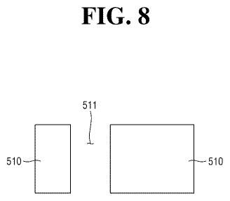

FIG. 7 is a cross-sectional view of the mask and a mask support portion, according to an embodiment, and FIG. 8 is an enlarged view of the through-hole of the mask frame in FIG. 7, according to an embodiment.

In an embodiment and referring to FIGS. 7 and 8, the mask 500 may include the mask frame 510, the through-hole 511 penetrating through a plate surface which may be formed on one side of the mask frame 510, and the other side of the mask frame 510 may be seated on and supported by the mask support portion 600.

Second, the method of measuring the gap between the mask 500 and the substrate 400 may include disposing the measurement member 700 on the mask frame 510 (S120 in FIG. 6).

Here, the measurement member 700 including the measurement hole 701 penetrating through the central area and the cover portion 720 corresponding to the remaining area excluding the measurement hole 701 may be prepared.

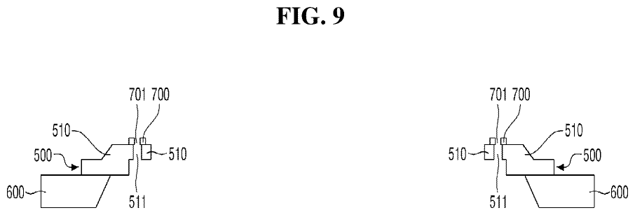

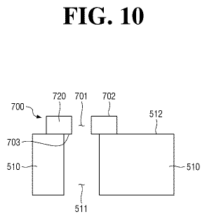

FIG. 9 is a cross-sectional view of the measurement member, the mask, and the mask support portion, according to an embodiment, and FIG. 10 is an enlarged view of the measurement member and the through hole of the mask frame of FIG. 9, according to an embodiment.

In an embodiment and referring to FIG. 9, the measurement member 700 may be attached onto the mask frame 510 in an area corresponding to the through-hole 511 of the mask frame 510, and may be attached onto the mask frame 510 by a welding method, such as a thermal bonding method. For example, in an embodiment, the measurement member 700 may be thermally bonded and fixed to the mask frame 510 by positioning the measurement member 700 so as to correspond and to be aligned to the through-hole 511 of the mask frame 510 and then welding an edge area of the measurement member 700. The welding may be spot welding.

In an embodiment and referring to FIG. 10, in the measurement member 700 fixed to the mask frame 510 by the thermal bonding method, the lower surface 703 of the cover portion 720 is attached to the upper surface 512 of the mask frame 510 at a position to cover a portion of the through-hole 511, where the measurement hole 701 has a smaller size diameter than the through-hole 511 and is positioned to be aligned with the through-hole 511.

Third, in an embodiment, the method of measuring the gap between the mask 500 and the substrate 400 may include disposing the substrate 400 on the upper side of the mask frame 510 (S130 in FIG. 6).

Here, in an embodiment, the substrate 400 may be disposed on the upper side of the mask frame 510 in a state in which the substrate 400 is supported by the electrostatic chuck 300 which is positioned on the lower side of the magnetic force generator 200.

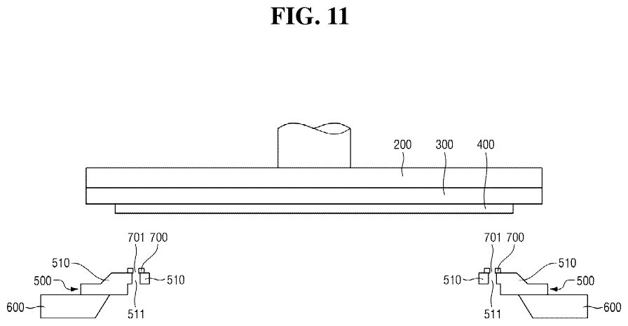

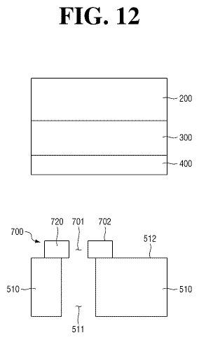

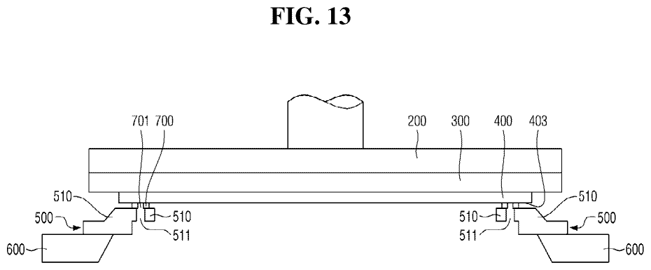

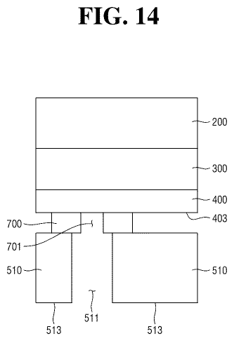

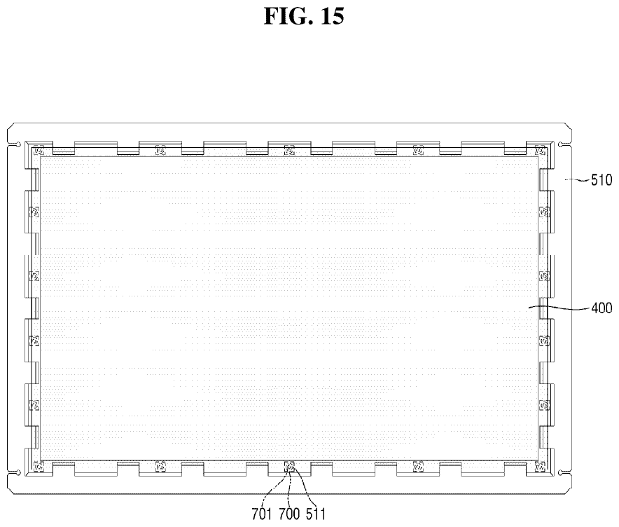

According to embodiments, FIG. 11 is a view illustrating a state in which the substrate 400 is disposed on the upper surface of the measurement member 700 and the mask 500 so as to be spaced apart from the measurement member 700 and the mask 500, FIG. 12 is an enlarged view of a partial area of the substrate 400, the measurement member 700, and the mask 500 of FIG. 11, FIG. 13 is a view illustrating a state in which the substrate 400 is disposed on the measurement member 700 and the mask 500, FIG. 14 is an enlarged view of a partial area of the substrate 400, the measurement member 700, and the mask 500 of FIG. 13, and FIG. 15 is a top view of the substrate 400, the measurement member 700, and the mask 500 of FIG. 13 viewed from above.

In an embodiment and referring to FIGS. 11 and 12, as an initial position, the substrate 400 may be positioned to be spaced apart from the upper surface 702 of the cover portion 720 and the upper surface 512 of the mask frame 510 in a state in which it is supported by the electrostatic chuck 300 positioned on the lower side of the magnetic force generator 200.

In an embodiment and referring to FIGS. 13 and 14, the substrate 400 may be moved from the initial position of FIGS. 11 and 12 and finally positioned on the mask frame 510. In this case, the substrate 400 may be moved toward the mask 500 or the mask 500 may be moved toward the substrate 400.

In an embodiment and referring to FIG. 14, while in the state in which the substrate 400 is supported by the electrostatic chuck 300 positioned on the lower side of the magnetic force generator 200, the substrate 400 is in contact with the measurement member 700, and one end of the measurement hole 701 of the measurement member 700 is closed by the substrate 400. Accordingly, a portion of the lower surface 403 of the substrate 400 may be exposed through the through-hole 511 and the measurement hole 701.

In an embodiment and referring to FIG. 15, based on a top view of the substrate 400 viewed from above in a state in which the substrate 400 is positioned on the mask frame 510, an edge area of the substrate 400 may be disposed to cover partial areas of the edges of the measurement hole 701, the measurement member 700, the through-hole 511, and the mask frame 510.

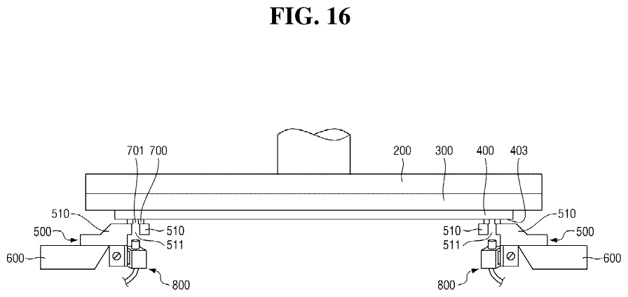

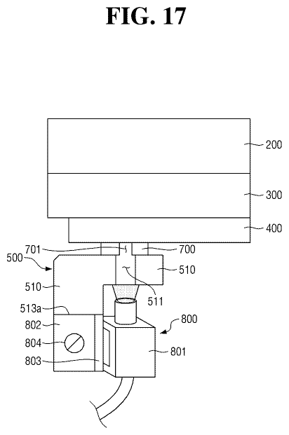

Fourth, in an embodiment and referring to FIG. 16 and FIG. 17, the method of measuring the gap between the mask 500 and the substrate 400 may include disposing the measurement camera module 800 on the lower side of the mask frame 510 (S140 in FIG. 6).

Here, the measurement camera module 800 including the measurement camera 801, the magnetic force applying portion 802, and the connection support portion 803 may be coupled to the lower side of the mask frame 510 at the position corresponding to the through-hole 511.

According to embodiments, FIG. 16 is a view illustrating a state in which a measurement camera module is disposed on the lower side of the mask frame, and FIG. 17 is an enlarged view of an installation area of the measurement camera module of FIG. 16.

In an embodiment and referring again to FIGS. 16 and 17, when a magnetic force generated by the magnetic force applying portion 802 is applied to the connection support portion 803 in a state in which the measurement camera 801 is coupled to the connection support portion 803, the connection support portion 803 may be attached to the mask frame 510 (which is made of metal) by the magnetic force.

For example, in an embodiment, when the on/off switch 804 of the magnetic force applying portion 802 is changed to the on-state in a state where the measurement camera module 800 in which the measurement camera 801, the connection support portion 803, and the magnetic force applying portion 802 are integrated with each other is brought into contact with the contact lower surface 513a of the mask frame 510, the magnetic force applying portion 802 may generate a magnetic force, and the magnetic force of the magnetic force applying portion 802 may be applied to the connection support portion 803. Accordingly, the connection support portion 803 made of the magnetic material is coupled to the contact lower surface 513a of the mask frame 510 by the magnetic force, and thus, the measurement camera module 800 may be fixed to the lower side of the mask frame 510.

Here, in an embodiment, the measurement camera module 800 may be coupled by the magnetic force, but a coupling means is not limited thereto, and a lighting device may be formed integrally with the measurement camera module 800, but is not limited thereto.

Fifth, in an embodiment, the method of measuring the gap between the mask 500 and the substrate 800 may include measuring distances through the measurement camera 801 (S150 in FIG. 6).

In an embodiment, the measurement camera 801 may measure the distances to the measurement member 700 and the substrate 400 through the through-hole 511 and the measurement hole 701.

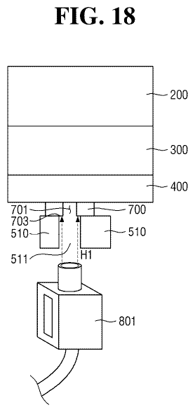

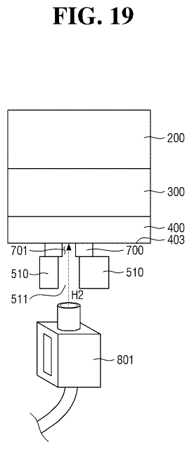

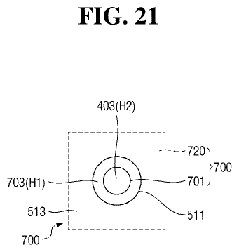

According to embodiments, FIG. 18 is a view illustrating a state in which a measurement camera of FIG. 17 measures a first distance, FIG. 19 is a view illustrating a state in which the measurement camera of FIG. 17 measures a second distance, FIG. 20 is a view illustrating the first and second distances measured by the measurement camera of FIG. 17, and FIG. 21 is a view illustrating a state of a lower surface of the mask frame when the measurement camera of FIG. 17 measures the second distance.

In an embodiment and referring to FIGS. 18, 20, and 21, the measurement hole 701 has a smaller size than the through-hole 511, and thus, a portion of the lower surface 703 of the cover portion 720 is exposed through the through-hole 511. Accordingly, the measurement camera 801 may measure the first distance H1 to the lower surface 703 of the cover portion 720 which is exposed through the through-hole 511.

In an embodiment and referring to FIGS. 19, 20, and 21, one side of the measurement hole 701 is covered by the lower surface 403 of the substrate 400 and the other side of the measurement hole 701 is aligned with the through-hole 511, and thus, a portion of the lower surface 403 of the substrate 400 is exposed by the measurement hole 701 and the through-hole 511. Accordingly, the measurement camera 801 may measure the second distance H2 to the lower surface 403 of the substrate 400 that is exposed through the through-hole 511 and the measurement hole 701.

In an embodiment and as described above, when the measurement of the first distance H1 from the measurement camera 801 to the lower surface 703 of the cover portion 720 and the second distance H2 from the measurement camera 801 to the lower surface 403 of the substrate 400 is completed, the controller 900 may calculate a difference value (H1−H2) between the first distance H1 and the second distance H2 as the gap between the substrate 400 and the mask 500. For example, the controller 900 may decide that the gap between the substrate 400 and the mask 500 becomes greater as the difference value (H1−H2) becomes smaller than about 0, may decide that the gap between the substrate 400 and the mask 500 becomes smaller as the difference value (H1−H2) becomes closer to about 0, and may decide that the gap between the substrate 400 and the mask 500 does not occur when the difference value (H1−H2) almost converges to about 0.

In an embodiment, the method of measuring the gap between the mask 500 and the substrate 400 may further include decoupling the measurement camera 801 from the mask frame 510 when the measurement of the distances is completed through the measurement camera 801.

For example, in an embodiment, in the case where the measurement of the distances is completed while in a state in which the measurement camera module 800 is coupled to the contact lower surface 513a of the mask frame 510, when the on-off switch 804 of the magnetic force applying portion 802 is changed from the on-state to the off-state, the magnetic force of the magnetic force applying portion 802 that is being applied to the connection support portion 803 is blocked, such that coupling force between the connection support portion 803 and the contact lower surface 513a of the mask frame 510 made of the metal by the magnetic force is released, and thus, the measurement camera module 800 may be decoupled from the lower side of the mask frame 510.

Here, in an embodiment, the processes of coupling and decoupling the measurement camera module 800 in order to measure the gap may be repeatedly performed to correspond to the number of through-holes 511. For example, when a plurality of through-holes 511 are formed, processes of installing the measurement camera module 800 at a position corresponding to one through-hole 511, measuring a gap through the measurement camera module 800, and then decoupling the measurement camera module 800 and installing the measurement camera module 800 at a position corresponding to another through-hole 511, measuring a gap through the measurement camera module 800, and then decoupling the measurement camera module 800 may be repeatedly performed. Measurement camera modules 800 of which the number corresponds to all through-holes 511 may also be prepared, be installed in the respective through-holes 511 at the same time, measure gaps, and then be decoupled.

As described above, with the deposition apparatus 1, according to an embodiment, it is possible to perform non-destructive measurement without damaging the substrate 400 and the mask frame 510 in measuring the gap, it is possible to measure the gap while simply changing a position of the measurement camera 801, and it is possible to accurately measure the gap at the same position even when measuring the gap several times because a gap measurement position is specified by the measurement member 700. In addition, by using the measurement camera 801, errors due to scattering of light may be fewer, and it is possible to confirm and discriminate an actual image for each measurement position.

In concluding the detailed description, those skilled in the art will appreciate that many variations and modifications can be made to the preferred embodiments without substantially departing from the principles of the invention. Therefore, the disclosed embodiments of the invention are used in a generic and descriptive sense only and not for purposes of limitation. Each component specifically shown in the embodiments of the invention can be implemented by modification, and such modifications and differences related to application should be construed as being included in the scope of the invention. Moreover, the embodiments or parts of the embodiments may be combined in whole or in part without departing from the scope of the invention.

What is claimed is:

1. A deposition apparatus comprising:
a substrate;
a mask disposed on a first surface of the substrate and including a mask frame supporting an edge area of the substrate;
a through-hole formed in the mask frame along the edge area of the substrate;
a measurement member disposed between the substrate and the mask frame at a position corresponding to the through-hole, wherein the measurement member includes a measurement hole connected to the through-hole; and
a measurement camera disposed on a first surface of the mask frame at the position corresponding to the through-hole,
wherein the measurement camera measures a first distance to the measurement member exposed through the through-hole and a second distance to the substrate exposed through the measurement hole.

2. The deposition apparatus of claim 1, wherein the measurement member is positioned on a second surface of the mask frame to be disposed opposite to the first surface of the mask frame.

3. The deposition apparatus of claim 2, wherein the measurement member further includes a cover portion, wherein the cover portion is an area other than the measurement hole, and
the measurement hole is positioned at a center of the cover portion and is formed to have a smaller size than the through-hole and to penetrate through the cover portion.

4. The deposition apparatus of claim 3, wherein the cover portion is attached to the second surface of the mask frame to open a portion of the through-hole to the same size as the measurement hole and to cover the remaining area of the through-hole.

5. The deposition apparatus of claim 1, wherein the measurement member is formed as a thin film.

6. The deposition apparatus of claim 1, further comprising a controller storing the first distance and the second distance measured by the measurement camera and calculating a gap between the substrate and the mask, wherein the gap is a difference value between the stored first distance and second distance.

7. The deposition apparatus of claim 1, wherein the measurement camera is coupled to and decoupled from the first surface of the mask frame at the position corresponding to the through-hole.

8. The deposition apparatus of claim 7, wherein the mask frame includes a metal, and
the measurement camera includes a magnetic force applying portion for coupling the measurement camera to the mask frame by generating a magnetic force and for decoupling the measurement camera from the mask frame by blocking the magnetic force.

9. The deposition apparatus of claim 8, further comprising a connection support portion positioned between the measurement camera and the magnetic force applying portion to connect the measurement camera to the magnetic force applying portion.

10. The deposition apparatus of claim 1, wherein the mask further includes a mask pattern portion positioned in a central area of the mask frame and disposed on the first surface of the substrate.

11. The deposition apparatus of claim 1, further comprising a mask support portion positioned on the first surface of the mask frame together with the measurement camera to support the mask on the first surface of the mask frame.

12. The deposition apparatus of claim 1, further comprising:
an electrostatic chuck (ESC) positioned on a second surface of the substrate to be opposite to the first surface of the substrate; and
a magnetic force generator positioned on a first surface of the electrostatic chuck.

13. A mask for a deposition apparatus, comprising:
a mask pattern portion;
a mask frame positioned at an edge of the mask pattern portion;
a through-hole formed in the mask frame; and
a measurement member positioned on the mask frame at a position corresponding to the through-hole and including a measurement hole connected to the through-hole.

14. The mask for a deposition apparatus of claim 13, wherein the measurement member further includes a cover portion that is an area other than the measurement hole, and
the measurement hole is positioned at a center of the cover portion and is formed to have a smaller size than the through-hole and to penetrate through the cover portion.

15. The mask for a deposition apparatus of claim 14, wherein the cover portion is attached onto the mask frame to open a portion of the through-hole to the same size as the measurement hole and to cover the remaining area of the through-hole.

16. A method of measuring a gap between a mask for a deposition apparatus and a substrate, the method comprising:
preparing a mask including a mask pattern portion and a mask frame positioned at an edge of the mask pattern portion and having at least one through-hole;
disposing a measurement member on the mask frame, the measurement member having a measurement hole connected to the through-hole;
disposing a substrate on an upper side of the mask frame;
disposing a measurement camera on a lower side of the mask frame; and
measuring distances through the measurement camera,
wherein the measurement camera measures a first distance to the measurement member exposed through the through-hole and a second distance to the substrate exposed through the measurement hole.

17. The method of claim 16, wherein the disposing of the measurement member on the mask frame includes thermally bonding the measurement member onto the mask frame.

18. The method of claim 16, wherein the measuring of the distances through the measurement camera includes:
coupling the measurement camera to the lower side of the mask frame to correspond to the through-hole; and
decoupling the measurement camera from the mask frame when the measurement of the distances is completed, wherein
the coupling of the measurement camera and the decoupling of the measurement camera are repeated to correspond to the number of at least one through-hole.

19. The method of claim 18, wherein the disposing of the measurement camera further includes disposing a magnetic force applying portion for coupling and decoupling the measurement camera to and from the mask frame by generating and blocking a magnetic force, and wherein
the magnetic force applying portion couples the measurement camera to the mask frame by generating the magnetic force, and
the magnetic force applying portion decouples the measurement camera from the mask frame by blocking the magnetic force.

20. The method of claim 16, further comprising calculating a gap between the mask for a deposition apparatus and the substrate, wherein the gap is a difference value between the first distance and the second distance.
